(19) United States
(12) Patent Application Publication
(10) Pub. No.: US 2019/0027424 A1
(43) Pub. Date: Jan. 24, 2019

(54) HIGH STRENGTH HIGH PERFORMANCE REINFORCED VAPOR CHAMBER AND RELATED HEATSINKS

(71) Applicant: HEATSCAPE.COM, INC., Morgan Hill, CA (US)

(72) Inventors: Ali Mira, Morgan Hill, CA (US); Yashar Mira, Morgan Hill, CA (US); Michael Mira, Morgan Hill, CA (US)

(21) Appl. No.: 15/654,068

(22) Filed: Jul. 19, 2017

(51) Int. Cl. H01L 23/433; H01L 23/373; H01L 23/367; H01L 23/40; H01L 23/427; B65D 85/30; B65D 81/18

(52) U.S. Cl. CPC H01L 23/433; H01L 23/3736; H01L 23/3672; H01L 2023/405; H01L 23/427; B65D 85/30; B65D 81/18; H01L 23/4006

(57) ABSTRACT

Disclosed are vapor chamber heatsinks for conducting heat away from electronic components, such as computer chips, in particular, the vapor chamber heatsink that includes a heatsink with cooling fins, a vapor chamber base having a vapor chamber, a thermal interface disposed on the vapor chamber base, and an internal frame. The interior of the vapor chamber is reinforced by a plurality of sleeved pillars disposed throughout the vapor chamber, which resist compressive forces exerted on the vapor chamber from mounting and prevent the vapor chamber from being crushed, even in the presence of compressive forces large enough to significantly reduce a thickness of the thermal interface. These sleeve pillars do not compromise the high thermal conductivity of the vapor chamber, which results is a vapor chamber heatsink that is capable of dissipating high thermal loads while withstanding high compressive forces.

### FIELD OF THE INVENTION

The present invention relates to vapor chambers, and more specifically to vapor chamber devices having a reinforced structural design.

### BACKGROUND OF THE INVENTION

Chips (e.g., microchips or integrated circuits) generate heat when used. Central processing units (CPUs) and graphics processing units (GPUs) are two examples of chips that can generate a tremendous amount of heat as a result of performing numerous, extremely high-speed operations required for executing computer programs. That heat needs to be dissipated from the chip in order to allow the chip to operate efficiently. The computer industry is continually innovating cooling systems to address the unique and demanding cooling requirements of chips that produce large amounts of heat.

Frequently, these chips are encapsulated in a packaging (e.g, an I.C. package) to allow for handling. The package has an external case and the temperature of this case (T_{case}) is a critical temperature for thermal design consideration. For a packaged chip to operate and perform properly, the package's case temperature must be maintained. Heatsinks have been typically used to cool these chips. The heatsink is placed in contact with the I.C. package and used to conduct heat away from the chip and towards cooling fins on the heatsink, which provides a large surface area for airflow to efficiently remove the heat from the heatsink through convection, conduction, and radiation (although to a lesser extent). Some heatsinks are used with vapor chambers to improve cooling by taking advantage of the high effective thermal conductivity of vapor chambers. A vapor chamber is a sealed vessel containing fluid that vaporizes in the vicinity of the hot component. The vapor migrates to a cooler surface of the vapor chamber, where it condenses and returns to the vicinity of the hot component. This vaporization and condensation cycle improves heat transfer from the hot component to the heatsink. Thus, some vapor chamber devices combine the use of vapor chambers with the cooling fins of traditional heatsinks. For instance, the vapor chamber can be used to move heat away from the package (e.g., the vapor chamber can be placed in contact with the package) and towards the cooling fins.

However, there are certain challenges associated with the use of vapor chambers. Vapor chambers are fragile and are easily damaged by the forces that may be present under high thermal load conditions when the vapor chamber is mounted to the circuit board housing the chip. At the same time, improving the durability of the vapor chamber can compromise the desired thermal characteristics of the vapor chamber device.

### BRIEF SUMMARY OF THE INVENTION

The embodiments described in the present disclosure are directed to reinforced vapor chambers (e.g., containing columnar reinforcing structures) that prevent the vapor chambers from being crushed when used in a vapor chamber heatsink assembly, which is a device that includes a vapor chamber coupled to a heatsink. The reinforced structure of the vapor chamber also helps preserve the desired thermal characteristics of the vapor chamber and the vapor chamber heatsink assembly. Thus, the durability of the vapor chamber is improved in a manner that does not also compromise the desired thermal characteristics of the vapor chamber and the vapor chamber heatsink assembly.

The embodiments are also directed to the use of a strengthening mounting plate with the vapor chamber heatsink assembly. The mounting plate is positioned on the other side of the circuit board as the vapor chamber heatsink assembly, and the vapor chamber heatsink assembly is mounted to the circuit board and the mounting plate through the use of fasteners that extend through the circuit board and the mounting plate. The mounting plate allows for high clamping forces to be applied against the chip package (e.g., by the vapor chamber heatsink assembly) without subjecting the circuit board itself to high bending forces that may be introduced from mounting the vapor chamber heatsink assembly. This prevents damage to the circuit board and the structures neighboring the chip.

One embodiment of the present application is a vapor chamber heatsink assembly that may include a finned heatsink with a plurality of cooling fins, with the heatsink placed atop a vapor chamber such that the plurality of cooling fins are directed away from the vapor chamber. The vapor chamber heatsink assembly may have a vapor chamber that is configured to be placed over a computing chip (e.g., a CPU). The vapor chamber heatsink assembly may include a thermal interface positioned between the vapor chamber and the chip, and the thermal interface may help conduct heat away from the chip. In some embodiments, the vapor chamber heatsink assembly may include an integrated frame (e.g., a steel frame) in contact with the vapor chamber that provides additional support for vapor chamber heatsink assembly.

The vapor chamber heatsink assembly may have mounting holes that traverse through the heatsink portion, the vapor chamber, and/or the steel frame. These mounting holes are configured to receive fasteners (e.g., standoffs or mounting screws) that are usable to mount the vapor chamber heatsink assembly to the circuit board of the computing chip via corresponding mounting holes in the circuit board. In some embodiments, the vapor chamber heatsink assembly may include a mounting plate that can be installed on the other side of the circuit board (e.g., the mounting plate and vapor chamber heatsink assembly can sandwich the circuit board). The mounting plate may be configured to receive the fasteners so that the vapor chamber heatsink assembly can be mechanically fixed to the mounting plate rather than directly to the circuit board, which relieves tension and stress in the circuit board.

In some embodiments, mounting the vapor chamber heatsink assembly (e.g., attaching the vapor chamber heatsink to the circuit board or the mounting plate) may generate a large compressive force on the computing chip, the thermal interface, and the vapor chamber. The thermal interface may be configured to reduce in thickness when subjected to this large compressive force, which improves thermal conductivity. In some embodiments, the vapor chamber may be reinforced internally by a plurality of sleeved pillars that prevent the vapor chamber from being crushed when subjected to this large compressive force while also promoting thermal conductivity across the vapor chambers.

The above summarized embodiments are described in further detail below by the following detailed description in conjunction with the accompanying drawings.

### BRIEF DESCRIPTION OF THE DRAWINGS

FIG. 1A illustrates a top perspective view of a vapor chamber in accordance with embodiments of the present disclosure.

FIG. 1B illustrates a bottom perspective view of vapor chamber in accordance with embodiments of the present disclosure.

FIG. 2A illustrates an exploded view of a vapor chamber with a reinforced pillar structure in accordance with embodiments of the present disclosure.

FIG. 2B illustrates an interior view of a vapor chamber with a reinforced pillar structure in accordance with embodiments of the present disclosure.

FIG. 3 illustrates a top perspective view of a reinforcing structure used in a reinforced vapor chamber.

FIG. 4 illustrates an exploded view of a vapor chamber heatsink assembly in accordance with embodiments of the present disclosure.

FIG. 5A illustrates a top perspective view of vapor chamber heatsink assembly being mounted in accordance with embodiments of the present disclosure.

FIG. 5B illustrates a top perspective view of a mounted vapor chamber heatsink assembly in accordance with embodiments of the present disclosure.

FIG. 5C illustrates a bottom perspective view of a mounted vapor chamber heatsink assembly in accordance with embodiments of the present disclosure.

FIG. 6A illustrates a top perspective view of a vapor chamber heatsink assembly and its packaging in accordance with embodiments of the present disclosure.

FIG. 6B illustrates a top perspective view of a vapor chamber heatsink assembly seated in its packaging in accordance with embodiments of the present disclosure.

FIG. 6C illustrates a top perspective view of a foam carrier used to ship packages of vapor chamber heatsink assemblies in accordance with embodiments of the present disclosure.

### DETAILED DESCRIPTION OF THE INVENTION

The present disclosure relates generally to vapor chambers with a reinforced design that prevents the vapor chamber from being crushed, while also preserving the desired thermal characteristics of the vapor chamber. One application of these vapor chambers is as part of a vapor chamber heatsink assembly, which can be an assembly that includes a heatsink coupled to a vapor chamber. This vapor chamber heatsink assembly may be positioned over an I.C. package, such that the vapor chamber contacts the package (e.g., through a thermal interface) and the heatsink is positioned above the vapor chamber. When this vapor chamber heatsink assembly is mounted to the circuit board, the vapor chamber heatsink assembly can be used to draw heat away from the package and towards the heatsink.

The reinforced vapor chamber is further capable of use with other thermal dissipation devices. For instance, other than a finned heatsink, the vapor chamber may be used with radial heatsinks, spiral heatsinks, other cold plates, Peltier's and thermoelectric coolers, heaters, heat pipes, radiators, water cooling systems, and so forth.

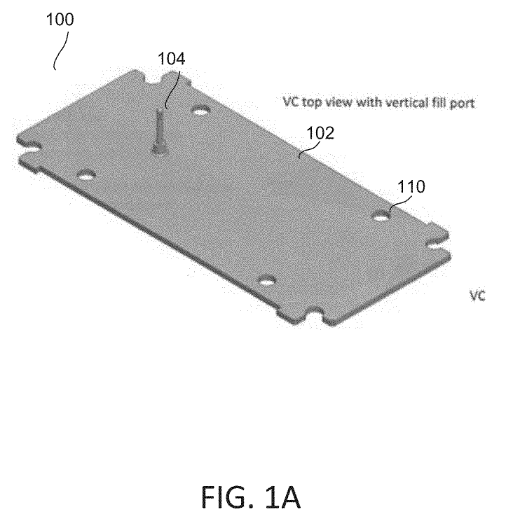

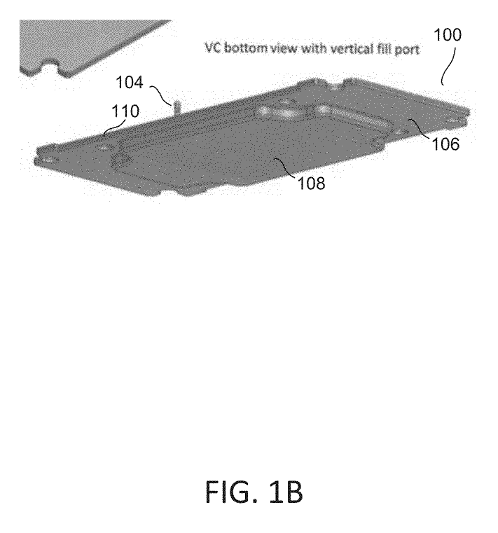

FIG. 1A provides a top perspective view of a vapor chamber, while FIG. 1B provides a bottom perspective view of the same vapor chamber .

In some embodiments, a vapor chamber 100 includes a top plate 102 and a bottom plate 106. The vapor chamber 100 may have a recess portion 108 that is defined by the top plate 102 and a cavity formed in the bottom plate 106, such that the recess portion 108 is enclosed when the top plate 102 and the bottom plate 106 are fitted together as shown in the figures. The top plate 102 may have a fill port 104 leading to the enclosed recess portion 108 that allows liquids to be added to the recess portion 108 through the fill port 104.

In some embodiments, the vapor chamber 100 may have mounting holes 110 for receiving fasteners or other suitable mounting components. The mounting holes 110, fasteners, and/or mounting components may function together to attach the vapor chamber 100 to a PCB (e.g., containing the I.C. package). The mounting holes 110 may traverse both the top plate 102 and the bottom plate 106 of the vapor chamber 100 such that a fastener (e.g., the shaft of a screw) can be threaded through one of the holes. In some embodiments, the mounting holes 110 are purposefully placed at locations such that they do not traverse through the recess portion 108. In some embodiments, the recess portion 108 has a rectangular cross section in the lateral plane, while in other embodiments, the recess portion 108 has a cross-like cross section in the lateral plane (e.g., as shown in the figures) in order to provide space for the mounting holes 110. However, the recess portion 108 can have any suitably shaped cross section in the lateral plane (e.g., it could have a circular cross section in the lateral plane if the I.C. package was also circularly shaped).

In some embodiments, the mounting holes 110 are purposefully placed at locations away from the lateral corners or edges of the vapor chamber 100. The vapor chamber 100 can take up a relatively large amount of area and there may be a tremendous amount of force that is exerted on the vapor chamber 100 (e.g., by an I.C. package pushing back against the bottom plate 106 of the vapor chamber 100). Accordingly, spacing the mounting holes 100 far apart from each other, such as at the very corners or edges of the vapor chamber 100, may cause the vapor chamber 100 and/or the circuit board to warp or deform when the vapor chamber 100 is attached to the PCB with fasteners.

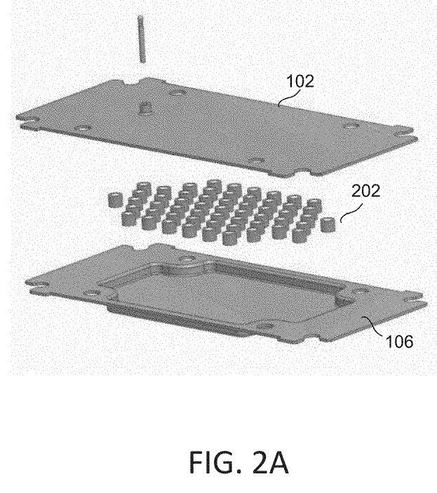

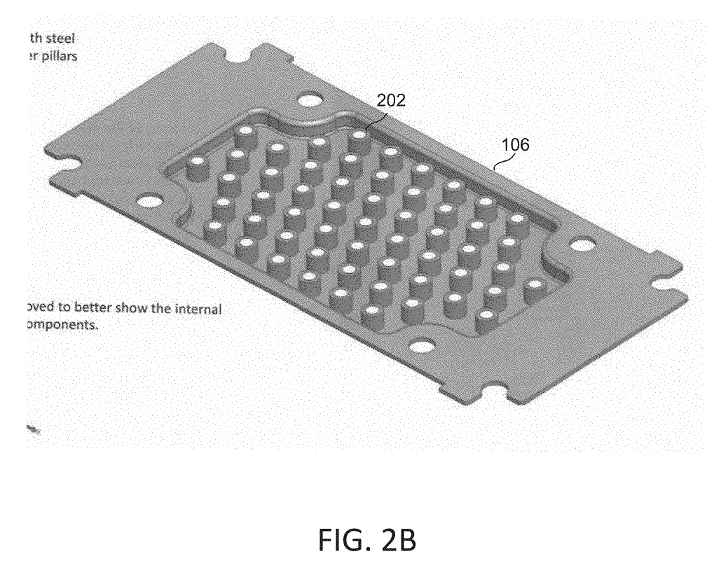

FIG. 2A illustrates an exploded view of a vapor chamber with a reinforced internal structure, while FIG. 2B illustrates an interior view of a vapor chamber with that reinforced internal structure.

In between the top plate 102 and the bottom plate 106 of the vapor chamber, there may be a plurality of columnar reinforcing structures 202 arranged in the cavity of the bottom plate 106. In some embodiments, the columnar reinforcing structures 202 may be jacketed or sleeved pillars. When the top plate 102 and the bottom plate 106 are fitted together to enclose the vapor chamber, the plurality of sleeved pillars may be enclosed within the vapor chamber. In some embodiments, the plurality of sleeved pillars may be fixed to the bottom plate 106 and/or the top plate 102, as a part of forming and/or assembling the vapor chamber. Each of the sleeved pillars may have a height that spans from the bottom plate 106 to the top plate 102 when the two plates are fitted together, such that each sleeved pillar provides support against forces applied to the top and bottom of the vapor chamber. Thus, the plurality of sleeved pillars may serve to reinforce the vapor chamber and help prevent the vapor chamber from being crushed or deformed by high forces applied to the vapor chamber. In some embodiments, this reinforced vapor chamber may be able to withstand a compressive force (e.g., in a vertical axis) of over 300 psi.

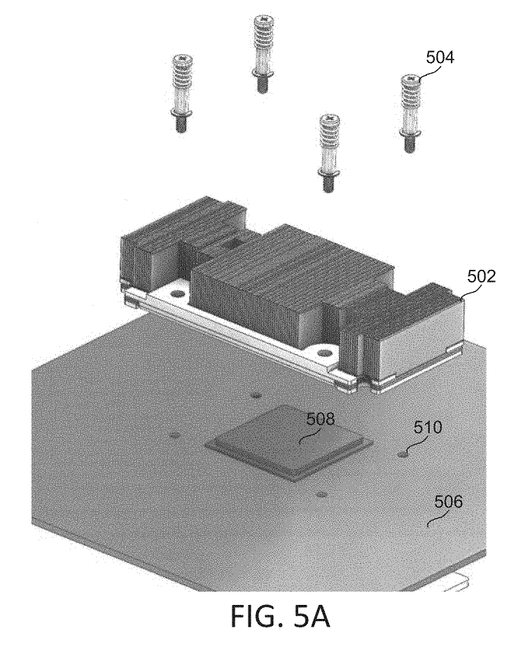

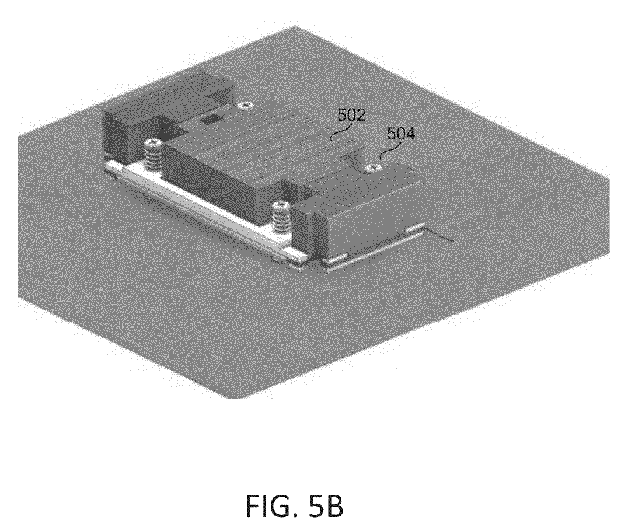

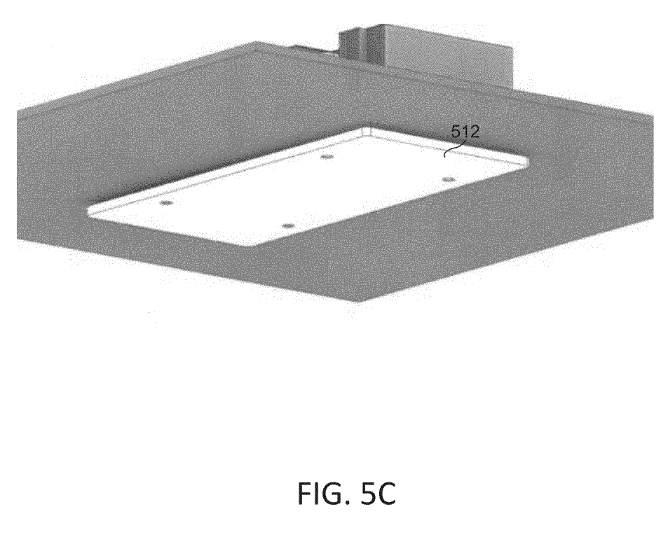

In some embodiments, the total lateral cross sectional area of the columnar reinforcing structures 202 may be selected or balanced against the lateral cross sectional area of the interior of the vapor chamber. For instance, the total lateral cross sectional area of the columnar reinforcing structures 202 may be increased either by adding more columnar reinforcing structures 202, changing the shapes of the columnar reinforcing structures 202, or by increasing the cross sectional area of each columnar reinforcing structure (e.g., by increasing the diameter). Increasing the total lateral cross section area of the columnar reinforcing structures 202 relative to the lateral cross sectional area of the interior of the vapor chamber may improve the compressive forth that the vapor chamber can withstand. However, too much of an increase in the total cross section area of the columnar reinforcing structures 202 may affect the desired thermal characteristics of the vapor chamber. Thus, in some embodiments, the total lateral cross sectional area of the columnar reinforcing structures 202, relative to the lateral cross sectional area of the interior of the vapor chamber, is chosen in order to provide the vapor chamber the ability to withstand over 300 psi of compressive force in the vertical axis without detracting from the effective thermal resistance of the vapor chamber heatsink assembly (described further in regards to FIG. 5A).

In some embodiments, the placement and arrangement of the columnar reinforcing structures 202 within the interior of the vapor chamber may be specifically chosen. For example, the columnar reinforcing structures 202 may be distributed relatively evenly within the interior of the vapor chamber such that each columnar reinforcing structures has a similar distance to neighboring columnar reinforcing structures. Or, the columnar reinforcing structures 202 may be concentrated where compressive force is most expected. For instance, the columnar reinforcing structures 202 may be concentrated in the middle of the vapor chamber if that area of the vapor chamber will be positioned over the chip and be subjected to forces from the I.C. package.

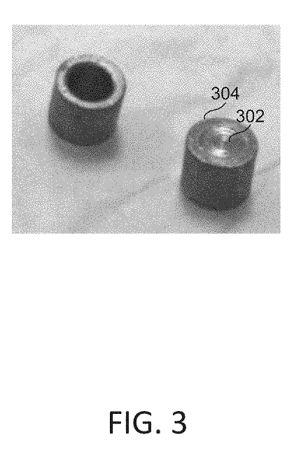

FIG. 3 illustrates a top perspective view of a reinforcing structure used in a reinforced vapor chamber. In particular, the figure illustrates an embodiment of a columnar reinforcing structure, such as the sleeved pillars discussed in regards to FIG. 2.

In some embodiments, the columnar reinforcing structure may be a sleeved pillar. The sleeved pillar may include an internal pillar 302 and a sleeve 304 that is configured to slide over the internal pillar 302, such that there is minimal space in-between the internal pillar and the sleeve 304. In other words, the internal pillar 302 may be jacketed in a sleeve 304.

In some embodiments, the internal pillar 302 can be formed of a first material while the sleeve 304 is formed of a second material. However, it is preferred for the sleeve 304 to be of the same, or similar, material as the remainder of the vapor chamber. For instance, the vapor chamber and/or the heatsink may be made of copper. Thus, it may be preferable for the sleeve 304 to also be made of copper.

In some embodiments, the second material has a compressive strength (e.g., resistance of a material to breaking under compression) that is lower than a compressive strength of the first material. In other words, the internal pillar 302 (formed of the first material) may provide more resistance against compressive forces than the sleeve 304 (formed of the second material). In some embodiments, the internal pillar 302 is formed of a material with high compressive strength (e.g., resistance of a material to breaking under compression), such as steel. In some embodiments, the second material has a thermal conductivity that is greater than a thermal conductivity of the first material. In other words, the sleeve 304 (formed of the second material) may have a greater thermal conductivity than the internal pillar 302 (formed of the first material).

In some embodiments, the second material will be selected for its thermal conductivity characteristics while the first material will be selected for its compressive strength characteristics. For instance, the internal pillar 302 may be formed of a material with high compressive strength, such as steel, while the sleeve 304 is formed of a material with high thermal conductivity, such as copper. This has practical benefits. For instance, the use of steel for the internal pillar 302 helps to reinforce the vapor chamber to withstand forces that would otherwise crush an internal pillar 302 made of a softer material (e.g., copper). However, steel has poor thermal conductivity; although placing a plurality of pillars made of steel in the vapor chamber would sufficiently reinforce the vapor chamber, doing so would affect the desired characteristics of the vapor chamber (e.g., make it less-effective at conducting heat). Outfitting each pillar with a sleeve 304 made of a copper would improve the heat-transfer capability between the bottom and top of the vapor chamber.

In some embodiments, the internal structure of the vapor chamber may include a plurality of steel pillars for strengthening the structure of the vapor chamber, with the steel pillars jacketed in a copper sleeve to allow for brazing the vapor chamber canister portions.

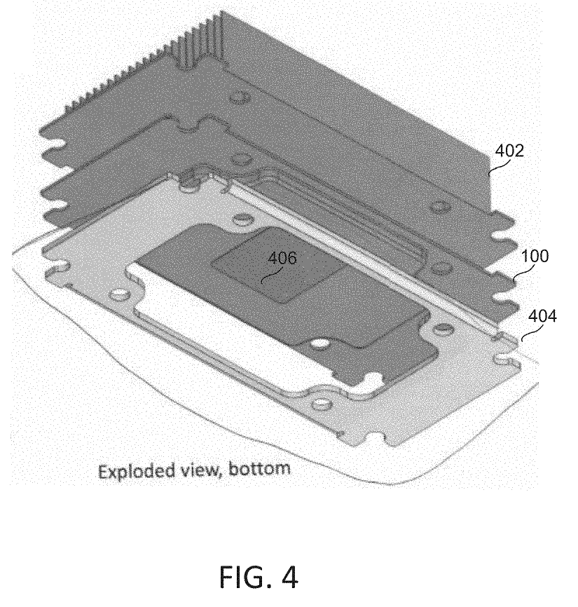

FIG. 4 illustrates an exploded view of a vapor chamber heatsink assembly that includes the reinforced vapor chamber described above.

As shown in the figure, a vapor chamber heatsink assembly may be an assembly that includes a vapor chamber 100 and a heatsink 402. The vapor chamber heatsink assembly may further include additional components, such as a steel frame 404, a thermal interface 406, mounting screws (not shown in FIG. 4), and a mounting plate (not shown in FIG. 4, but a mounting plate 512 is viewable in FIG. 5C).

The heatsink 402 may have an array of fins, and the heatsink 402 can be seated above the vapor chamber 100 with the fins directed away from the vapor chamber 100. The heatsink 402 may have mounting holes in it that can be aligned with the mounting holes of the vapor chamber 100, such that mounting screws can be passed through the mounting holes of the heatsink 402 and the mounting holes of the vapor chamber 100.

The vapor chamber 100 may be seated above the steel frame 404, which provides additional support and rigidity to the vapor chamber heatsink assembly. In some cases the steel frame 404 may be configured to contact the circuit board on which the vapor chamber heatsink assembly is installed. The steel frame 404 may also have mounting holes in it that can be aligned with the mounting holes of the vapor chamber 100, such that mounting screws can be passed through the respective mounting holes of the heatsink 402, the vapor chamber 100, and the steel frame 404.

There may be a thermal interface 406 located at the bottom of the vapor chamber 100 in the region of the vapor chamber 100 that is positioned over the I.C. package to be cooled (e.g., to make contact with the package). The thermal interface 406 may be made of any material that improves thermal conductivity between the chip and the vapor chamber 100, including a thermal pad or a layer of thermal grease.

FIG. 5A illustrates a top perspective view of vapor chamber heatsink assembly being mounted on a circuit board. FIG. 5B illustrates a top perspective view of that vapor chamber heatsink assembly once it has been mounted. FIG. 5C illustrates a bottom perspective view of that vapor chamber heatsink assembly once it has been mounted, in embodiments in which a mounting plate is used.

The vapor chamber heatsink assembly 502 is shown positioned over the case 508 of the I.C. package to be cooled. The mounting holes of the various components (e.g., the heatsink, vapor chamber, and steel frame) of the vapor chamber heatsink assembly 502 are all aligned and configured to receive the fasteners 504. In some embodiments, the fasteners 504 may be standoffs or screws. The aligned mounting holes in the vapor chamber heatsink assembly 502 are also configured to align with the mounting holes 510 in the circuit board 506 that surround the case 508. Thus, the fasteners 504 are able pass through the mounting holes of the vapor chamber heatsink assembly 502 and the mounting holes 510 in the circuit board 506 in order to fasten the vapor chamber heatsink assembly 502 to the circuit board 506.

In some embodiments, there may be a mounting plate 512 on the other side of the circuit board 506 that is configured to receive the fasteners 504. The mounting plate 512 may provide additional structural rigidity for mounting the vapor chamber heatsink assembly 502 to the circuit board 506. Without the mounting plate 512, the forces exerted by the fasteners 504 may bend and warp the circuit board 506 (especially if the fasteners 504 are spaced far apart from one another, whereby the larger distance between the fasteners 504 can create bending forces, especially with different loadings on the fasteners 504). The addition of the mounting plate 512 for receiving the fasteners 504 reduces the torque and compressive forces to which the circuit board 506 would be subject.

In some embodiments, the vapor chamber heatsink assembly 502 may be configured to withstand high compressive force. For example, mounting the vapor chamber heatsink assembly 502 to the circuit board 506 may result in a pressure of 300 psi being exerted on the bottom of the vapor chamber heatsink assembly 502. This high compressive force may serve to reduce the thickness of a thermal interface located on the bottom of the vapor chamber heatsink assembly 502 (e.g., the thermal interface 406). For instance, the thermal interface could have a thickness of 8 millimeters that compresses to a thickness of 3 millimeters as the thermal interface is compressed between the bottom of the vapor chamber heatsink assembly 502 and the top of the case 508.

In some embodiments, each fastener 504 (e.g., each standoff or mounting screw) may generate a compressive force of 50 kg when the vapor chamber heatsink assembly 502 is mounted. A total of four fasteners 504 would result in 200 kgs or more of compressive force. In some embodiments, each fastener 504 may include a screw and washer. Each fastener 504 may have a threaded standoff with a spring. As each fastener 504 is screwed in further, the compressive force generated through that particular fastener 504 is increased. Thus, a user mounting the vapor chamber heatsink assembly 502 may be able to have some control over the compressive force generated through each fastener 504 (and thus, the total compressive force) based on how much the user screws in each fastener 504.

In some embodiments, each fastener 504 may be a standoff with a configurable torque setting. Typically, this torque setting may be specified as part of the mounting instructions to ensure a proper compressive force is applied to compress the thermal interface down to 3 mils (three thousandths of an inch) in order for the vapor chamber heatsink assembly to effectively operate. In some embodiments, each fastener 504 or standoff may include a spring, a shoulder screw with a threaded end (e.g., at the distal end of the fastener), and a washer. The washer may be disposed on the threaded end of the shoulder screw, with the spring being located towards the proximal end of the shoulder screw. In some embodiments, the vapor chamber heatsink assembly 502 may be a thermal solution that is typically to the end user in a package or a kit form, which may also include a set of instructions and hardware (e.g., the fasteners 504) for proper mounting of the vapor chamber heatsink assembly 502 to the I.C. package. The set of instructions may include a torque setting for the fasteners 504 (e.g., mounting screws).

In some embodiments, the high thermal conductivity of the vapor chamber heatsink assembly 502 may allow the vapor chamber heatsink assembly 502 to effectively dissipate a thermal load of 400-600 W. The vapor chamber heatsink assembly 502 may be configured to have a “delta T” or temperature difference of 60 degrees Celsius across the vapor chamber heatsink assembly 502 while dissipating up to 600 W of thermal load. In some embodiments, the vapor chamber heatsink assembly 502 may have an effective thermal resistance between 0.1 and 0.2 degrees Celsius per watt. In some embodiments, the vapor chamber heatsink assembly 502 may have an effective thermal resistance of under 0.2 degrees Celsius per watt. In some embodiments, the vapor chamber heatsink assembly 502 may have an effective thermal resistance of about 0.1 degrees Celsius per watt.

For instance, the case 508 of the I.C. package may output a thermal load of 600 watts. If the vapor chamber heatsink assembly 502 has an effective thermal resistance of around 0.1 degrees Celsius per watt, then there would be a temperature differential across the vapor chamber heatsink assembly 502 of 60 degrees Celsius, calculated as 600 W * (0.1° C./W)=60° C. Thus, when the case 508 is outputting a thermal load of 600 W and has an ambient temperature of 20° C. at the fin tip, the temperature at the case would be 80° C. temperature of 80° C., or 60° C. more than the temperature at the fin tip or ambient. This assumes that the vapor chamber heatsink assembly 502 is in sufficient contact with the case 508 and there is sufficient airflow over the fins of the heatsink to dissipate the heat (e.g., an airflow of 500-1000 ft/m).

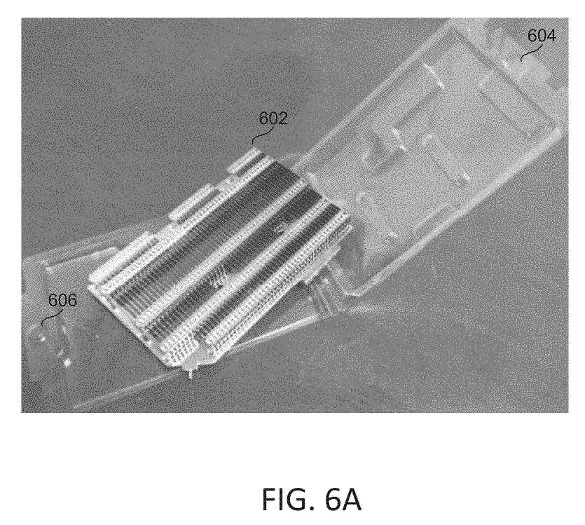

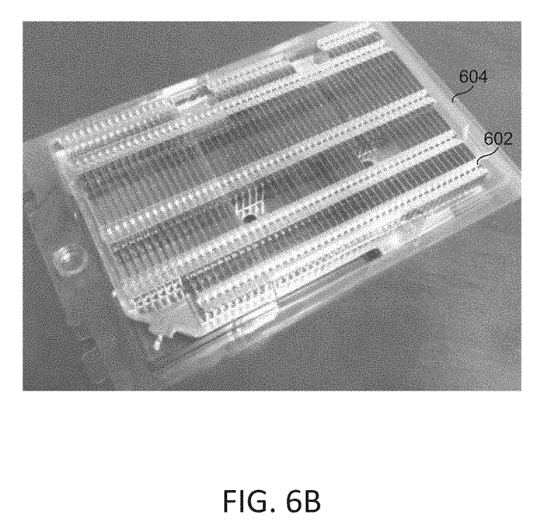

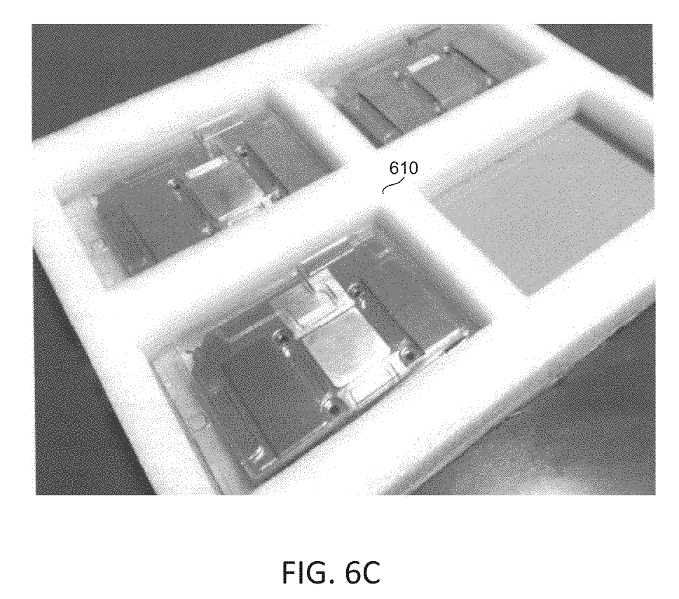

FIG. 6A illustrates a top perspective view of a vapor chamber heatsink assembly and its packaging in accordance with embodiments of the present disclosure. FIG. 6B illustrates a top perspective view of a vapor chamber heatsink assembly seated in that packaging.

In some embodiments, the packaging used to store the vapor chamber heatsink assembly 602 may be a plastic carrier 604. The plastic carrier 604 may have a clamshell configuration. The plastic carrier 604 may also have a lock 606 for keeping the two halves of the clamshell held together when the plastic carrier 604 is closed.

In some embodiments, the plastic carrier 604 may be configured to store both the heatsink and the vapor chamber of the vapor chamber heatsink assembly 602. In some embodiments, the plastic carrier 604 is configured to protect the delicate fin structure of the heatsink when the two halves of the clamshell of the plastic carrier 604 are locked together. In some embodiments, the plastic carrier 604 may be configured to hold a vapor chamber heatsink assembly 602 that has a thermal interface material pre-applied to it, and the plastic carrier 604 holds the vapor chamber heatsink assembly 602 in a way that the thermal interface material is not touched by the plastic carrier 604 when the clamshell is closed.

FIG. 6C illustrates a top perspective view of a foam carrier used to ship packages of vapor chamber heatsink assemblies in accordance with embodiments of the present disclosure.

In some embodiments, a foam carrier 610 has a cavity configured to receive a plastic carrier containing a vapor chamber heatsink assembly. In some embodiments, the foam carrier 610 may have a plurality of cavities for receiving multiple plastic carriers. In some of such embodiments, the foam carrier 610 may have four cavities as shown in the figure that allow up to four vapor chamber heatsink assemblies to be transported using the foam carrier 610. The cavities of the foam carrier 610 may also be configured to receive any components necessary for the attachment of the vapor chamber heatsink assembly to the circuit board (e.g., steel frames, mounting screws, mounting plate, and so forth).

In summary, the figures depict a vapor chamber with a reinforced design that includes columnar reinforcing structures for providing support to the vapor chamber. This vapor chamber can be utilized as a component of a vapor chamber heatsink assembly, which includes a heatsink coupled to the vapor chamber. The vapor chamber heatsink assembly may be positioned over an I.C. package and mounted to the circuit board containing the I.C. package, so that the vapor chamber heatsink assembly can be used to draw heat away from the package and towards the heatsink for dissipation. Since the vapor chamber is reinforced by the columnar reinforcing structures, the vapor chamber is able to withstand the high compressive forces involved in mounting the vapor chamber heatsink assembly to the circuit board that are also necessary for effective operation of the vapor chamber heatsink assembly. This vapor chamber heatsink assembly can be provided as part of a kit solution and transported within a plastic carrier. The vapor chamber heatsink assembly may have a pre-applied thermal interface that establishes effective thermal contact between the vapor chamber and the I.C. package, and that pre-applied thermal interface may allow the vapor chamber heatsink assembly to be quickly mounted on the circuit board (since the user would not have to apply a thermal interface). Accordingly, the plastic carrier may be specifically configured to hold the vapor chamber heatsink assembly without contacting or otherwise disrupting the pre-applied thermal interface.

Terminology

The terms “approximately”, “about”, and “substantially” as used herein represent an amount close to the stated amount that still performs a desired function or achieves a desired result. For example, the terms “approximately”, “about”, and “substantially” may refer to an amount that is within less than 10% of, within less than 5% of, within less than 1% of, within less than 0.1% of, and within less than 0.01% of the stated amount.

Although this invention has been disclosed in the context of certain preferred embodiments and examples, it will be understood by those skilled in the art that the present invention extends beyond the specifically disclosed embodiments to other alternative embodiments and/or uses of the invention and obvious modifications and equivalents thereof. In addition, while a number of variations of the invention have been shown and described in detail, other modifications, which are within the scope of this invention, will be readily apparent to those of skill in the art based upon this disclosure. It is also contemplated that various combinations or sub-combinations of the specific features and aspects of the embodiments may be made and still fall within the scope of the invention. Accordingly, it should be understood that various features and aspects of the disclosed embodiments can be combined with or substituted for one another in order to form varying modes of the disclosed invention. Thus, it is intended that the scope of the present invention herein disclosed should not be limited by the particular disclosed embodiments described above.

Similarly, this method of disclosure is not to be interpreted as reflecting an intention that any claim require more features than are expressly recited in that claim. Rather, inventive aspects may lie in a combination of fewer than all features of any single foregoing disclosed embodiment. Thus, the claims following the Detailed Description are hereby expressly incorporated into this Detailed Description, with each claim standing on its own as a separate embodiment.

What is claimed is:

1. A vapor chamber heatsink assembly, comprising:
a vapor chamber comprising:
a top plate;
a bottom plate; and
a plurality of sleeved pillars disposed throughout an interior of the vapor chamber, and wherein each sleeved pillar comprises:
an internal pillar formed of a first material; and
a sleeve formed of a second material, wherein the second material has a thermal conductivity that is greater than a thermal conductivity of the first material, and wherein the second material has a compression strength that is lower than a compression strength of the first material,
wherein the internal pillar and the sleeve of each sleeved pillar is physically coupled to both the top plate and the bottom plate;
a finned heatsink coupled to the vapor chamber , wherein the heatsink comprises a plurality of fins directed away from the vapor chamber;
a thermal interface disposed on an exposed side of the bottom plate of the vapor chamber;
an integrated frame coupled to the vapor chamber; and
a plurality of mounting holes, wherein each mounting hole is configured to receive a fastener for mounting the vapor chamber heatsink assembly to a circuit board,
wherein the vapor chamber heatsink assembly is configured to provide an effective thermal resistance of 0.1 degrees Celsius per watt while dissipating a thermal load of 600 watts,
wherein mounting the vapor chamber heatsink assembly to the circuit board causes a compressive force to be exerted on the thermal interface, wherein the compressive force is large enough to decrease a thickness of the thermal interface by five mils, and wherein the plurality of sleeved pillars in the vapor chamber prevent the vapor chamber from being crushed by the compressive force.

2. The vapor chamber heatsink assembly of claim 1, wherein the vapor chamber heatsink assembly further comprises a mounting plate for mounting the vapor chamber heatsink assembly to the circuit board, wherein the mounting plate is further configured to reduce any bending forces introduced to the circuit board from mounting the vapor chamber heatsink assembly to the circuit board.

3. The vapor chamber heatsink assembly of claim 1, wherein the interior of the vapor chamber has a rectangular cross section in a lateral plane.

4. The vapor chamber heatsink assembly of claim 1, wherein the interior of the vapor chamber has a cross-shaped cross section in a lateral plane.

5. The vapor chamber heatsink assembly of claim 1, wherein prior to the compressive force being exerted on the thermal interface, the thermal interface has a thickness of 8 mils.

6. The vapor chamber heatsink assembly of claim 5, wherein the compressive force is large enough to decrease the thickness of the thermal interface to 3 mils.

7. The vapor chamber heatsink assembly of claim 1, wherein the first material is steel.

8. The vapor chamber heatsink assembly of claim 1, wherein the second material is copper.

9. The vapor chamber heatsink assembly of claim 1, wherein the vapor chamber is made of copper.

10. The vapor chamber heatsink assembly of claim 1, wherein the heatsink is made of copper.

11. A kit comprising:
a plastic carrier having a clamshell configuration that can be opened and closed;
a vapor chamber heatsink assembly comprising:
a vapor chamber comprising:
a top plate;
a bottom plate; and
a plurality of sleeved pillars disposed throughout an interior of the vapor chamber, and wherein each sleeved pillar comprises:
an internal pillar formed of a first material; and
a sleeve formed of a second material, wherein the second material has a thermal conductivity that is greater than a thermal conductivity of the first material, and wherein the second material has a compression strength that is lower than a compression strength of the first material,
wherein the internal pillar and the sleeve of each sleeved pillar is physically coupled to both the top plate and the bottom plate;
a finned heatsink coupled to the vapor chamber, wherein the heatsink comprises a plurality of fins directed away from the vapor chamber;
an integrated frame coupled to the vapor chamber; and
a thermal interface disposed on an exposed side of the bottom plate of the vapor chamber,
wherein the plastic carrier is configured to hold the vapor chamber and the heatsink without the plastic carrier touching the thermal interface when the clamshell configuration is closed.

12. The kit of claim 11, wherein the kit further comprises a mounting plate for mounting the vapor chamber heatsink assembly to the circuit board, wherein the mounting plate is further configured to reduce any bending forces introduced to the circuit board from mounting the vapor chamber heatsink assembly to the circuit board.

13. The kit of claim 11, wherein the interior of the vapor chamber has a cross-shaped cross section in a lateral plane.

14. The kit of claim 11, wherein the interior of the vapor chamber has a cross-shaped cross section in a lateral plane.

15. The kit of claim 11, wherein the thermal interface has an uncompressed thickness of 8 mils.

16. The kit of claim 11, wherein the first material is steel.

17. The kit of claim 11, wherein the second material is copper.

18. The kit of claim 11, wherein the vapor chamber is made of copper.

19. The kit of claim 11, wherein the vapor chamber heatsink assembly is configured to provide an effective thermal resistance of 0.1 degrees Celsius per watt while dissipating a thermal load of 600 watts.

20. The kit of claim 11, wherein the vapor chamber heatsink assembly is configured to provide an effective thermal resistance of 0.1 degrees Celsius per watt while dissipating a thermal load of 600 watts and receiving 500 to 1000 feet per minute of airflow at the plurality of fins of the heatsink.
